(19) United States
(12) Patent Application Publication
(10) Pub. No.: US 2018/0020547 A1
(43) Pub. Date: Jan. 18, 2018

(54) UNDERLYING RECESSED COMPONENT PLACEMENT

(71) Applicants: Alex L. CHAN, Ottawa (CA); Paul J. BROWN, Ottawa (CA)

(72) Inventors: Alex L. CHAN, Ottawa (CA); Paul J. BROWN, Ottawa (CA)

(73) Assignee: ALCATEL-LUCENT CANADA INC., Ottawa (CA)

(21) Appl. No.: 15/209,230

(22) Filed: Jul. 13, 2016

(51) Int. Cl. H05K 1/18; G06F 17/50; H05K 3/00; H05K 1/11; H05K 3/46; H05K 3/34; H05K 1/02

(52) U.S. Cl. CPC H05K 1/183; H05K 3/341; G06F 17/5077; H05K 1/0298; H05K 1/111; H05K 3/4697; H05K 3/3494; G06F 17/5072; H05K 3/0026; H05K 3/0005; H05K 2201/09036; H05K 2201/10015; H05K 2201/10734; H05K 2203/0228

(57) ABSTRACT

An underlying recess is provided for component placement beneath Ball Grid Arrays allowing closer proximity for decoupling capacitors and other components. The underlying recess placement of components assists in minimizing reliability issues concerning surface mount components and provides closer proximity placement of components. The underlying recess placement of components is particularly useful for overcoming the problem of parasitic inductance of more distant component placements known in the art.

### TECHNICAL FIELD

The present invention relates to Ball Grid Arrays and is particularly concerned with proximate component placement, including decoupling components.

### BACKGROUND

As electronic integrated circuit (EIC) packages such as Ball Grid Array (BGA) packages increase in density, in interface connection density, and in clock speed, the requirements for electrically decoupling a BGA device become more stringent. It is advantageous to place these decoupling capacitors as close to the BGA pads as possible. Typical placement of surface-mount decoupling capacitors is adjacent to the BGA device on the same side of the electronic circuit board or on the opposite side of the electronic circuit board, connected by vias through the circuit board. Both of these techniques can introduce parasitic inductance due to the length of the routing leads and the length of the conductive path through the via itself.

One approach to providing component placement which maximizes proximity is placing the decoupling capacitors on the bottom of the BGA itself, amidst the grid array, as described in US Pat. Nos. U.S.8,806,420 “In-Grid On-Device Decoupling for BGA” and U.S.8,863,071 “De-Pop On-Device Decoupling for BGA”, the entire contents of which are incorporated herein by reference. A difficulty which arises with this approach is the possible reluctance of BGA manufactures to assume the responsibility and testing entailed with placement of the components on the BGA, as opposed to simply providing the BGA itself.

Therefore, it continues to be desirable to provide alternate methods of placing small components within close proximity of Ball Grid Arrays.

### SUMMARY

A brief summary of various exemplary embodiments is presented below. Some simplifications and omissions may be made in the following summary, which is intended to highlight and introduce some aspects of the various exemplary embodiments, but not to limit the scope of the invention. Detailed descriptions of a preferred exemplary embodiment adequate to allow those of ordinary skill in the art to make and use the inventive concepts will follow in later sections.

According to an aspect of the invention there is provided a through-hole printed circuit board (PCB) having a ball grid array (BGA) of BGA pads on one side of the PCB, arranged in a tight-pitch grid pattern; a milled recess on the same side of the PCB in the PCB adjacent and between a first and a second of the BGA pads of the ball grid array of BGA pads; the recess sized to contain a Surface Mount Component (SMC); a first pair of separated conductive pads at the bottom of the milled recess, each pad respectively conductively coupled to the first and second BGA pads.

In some embodiments of this aspect of the invention a second pair of separated conductive pads surround the opening of the milled recess, each pad respectively conductively coupled to the first and second BGA pads.

In some embodiments of this aspect of the invention the tight-pitch grid pattern has a 1 mm pitch. In some of these embodiments the SMC has a industry nominal 0201 size; and the first and second BGA pads are diagonally situated relative to the grid pattern. In others of these embodiments the SMC has a industry nominal 01005 size; and the first and second BGA pads are diagonally situated relative to the grid pattern.

In some embodiments of this aspect of the invention at least one BGA pad of the ball grid array of BGA pads has been removed; and the milled recess is located in the array grid where the at least one BGA has been removed. In some of these embodiments the SMC has an industry nominal 01005 size, in some an industry nominal 0201 size, in some an industry nominal 0402 size, and in some an industry nominal 0603 size.

In some embodiments of this aspect of the invention the milled recess was milled by a laser.

According to another aspect of the invention there is provided a method of manufacturing a multilayer PCB wherein the PCB has a ball grid array (BGA) of BGA pads on one side of the PCB arranged in a grid pattern; the method having the steps of: milling a recess on the same side of the PCB in the PCB adjacent and between a first and a second of the BGA pads of the ball grid array of BGA pads, the bottom of the recess having arranging a first pair of separated conductive pads at the bottom of the milled recess, each pad respectively conductively coupled to the first and second BGA pads; sizing the recess to contain a Surface Mount Component (SMC); placing solder paste in the first pair of separated conductive pads; placing solder paste on the ball grid array (BGA) of BGA pads; placing an SMC within the recess; placing a BGA component over the SMC; reflow soldering the SMC component and the BGA component.

In some embodiments of this aspect of the invention the milling is performed by a laser.

In some embodiments of this aspect of the invention there are the further steps of the multilayer PCB having a second pair of separated conductive pads surrounding the opening of the milled recess, each pad respectively conductively coupled to the same first and second BGA pads as the respective conductive pads at the same end of the recess; and prior to the step of placing an SMC within the recess, placing solder paste on the second pair of separated conductive pads.

In some embodiments of this aspect of the invention the SMC is a capacitor.

In some embodiments of this aspect of the invention the first and second BGA pads are diagonally situated relative to the grid pattern

In some embodiments of this aspect of the invention at least one BGA pad of the ball grid array of BGA pads has been removed; and the milling of the recess is located in the array grid where the at least one BGA has been removed.

According to yet another aspect of the invention there is provided a computer aided design tool implemented on a computing device for accommodating a multilayer printed circuit board (PCB) wherein the PCB has a ball grid array (BGA) of BGA pads on one side of the PCB arranged in a grid pattern having: a design tool mode configured to select two adjacent BGA pads on the printed circuit board (PCB) for connection to a two-lead component; a design tool mode configured to identify a placement of a recess between the two BGA pads for containing a Surface Mount Component (SMC); a design tool mode configured to identify a placement of separated component pads on an inner layer of the PCB so as to define a bottom of the recess; and a design tool mode configured to conductively connect the separated component pads to a respective BGA pad of the two BGA pads.

In some embodiments of this aspect of the invention the design tool further has a design tool mode configured to identify a placement of a second pair of separated conductive pads surrounding the opening of the milled recess; and a design tool mode configured to conductively connect the second pair respectively to the same first and second BGA pads as the respective conductive pads at the same end of the recess.

In some embodiments of this aspect of the invention the design tool further has a design tool mode configured to identify remove at least one BGA pad from the ball grid array of BGA pads and situate the recess in the array grid where the BGA pad has been removed.

### BRIEF DESCRIPTION OF THE DRAWINGS

In order to better understand various exemplary embodiments, reference is made to the accompanying drawings, wherein:

FIG. 1a shows a cross-sectional view of a portion of a fine-pitch through-hole multilayer circuit board according to an embodiment of the invention;

FIG. 1b shows a cross-sectional view of a laser etching a portion of the of the fine-pitch through-hole multilayer circuit board of FIG. 1;

FIG. 1c shows a cross-sectional view of a laser etching a further portion of the of the fine-pitch through-hole multilayer circuit board of FIG. 1;

FIG. 2a shows a cross-sectional view of solder paste applied within and adjacent to the laser etched recess of the of the fine-pitch through-hole multilayer circuit board of FIG. 1;

FIG. 2b shows a cross-sectional view of a surface mount component placed within the laser etched recess of the of the fine-pitch through-hole multilayer circuit board of FIG. 2a;

FIG. 2c shows a cross-sectional view of a BGA component placed over the laser etched recess of the of the fine-pitch through-hole multilayer circuit board of FIG. 2b;

FIG. 3a shows a top view of a copper land pattern on the top layer of a fine-pitch through-hole multilayer circuit board having a surface mount component mounted thereon according to an embodiment of the invention;

FIG. 3b shows a top view of a copper structure pattern on an inner layer of a fine-pitch through-hole multilayer circuit board according to an embodiment of the invention;

FIG. 3c shows a top view of a copper land pattern on the top layer of a fine-pitch through-hole multilayer circuit board relative to a pair of BGA landing pads according to an embodiment of the invention;

FIG. 4 shows a top view of a copper land pattern on the top layer of a fine-pitch through-hole multilayer circuit board relative to a grid of BGA landing pads according to an embodiment of the invention; and

FIG. 5 shows a flowchart of a series of method steps according to an embodiment of the invention.

To facilitate understanding, similar reference numerals have been used to designate elements having substantially the same or similar structure and/or substantially the same or similar function.

### DETAILED DESCRIPTION

The description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for pedagogical purposes to aid the reader in understanding the principles of the invention and the concepts contributed by the inventor(s) to furthering the art, and are to be construed as being without limitation to such specifically recited examples and conditions. Additionally, the term, “or,” as used herein, refers to a non-exclusive or (i.e., and/or), unless otherwise indicated (e.g., “or else” or “or in the alternative”). Also, the various embodiments described herein are not necessarily mutually exclusive, as some embodiments may be combined with one or more other embodiments to form new embodiments.

Referring now to the drawings, in which like numerals refer to like components or steps, there are disclosed broad aspects of various exemplary embodiments.

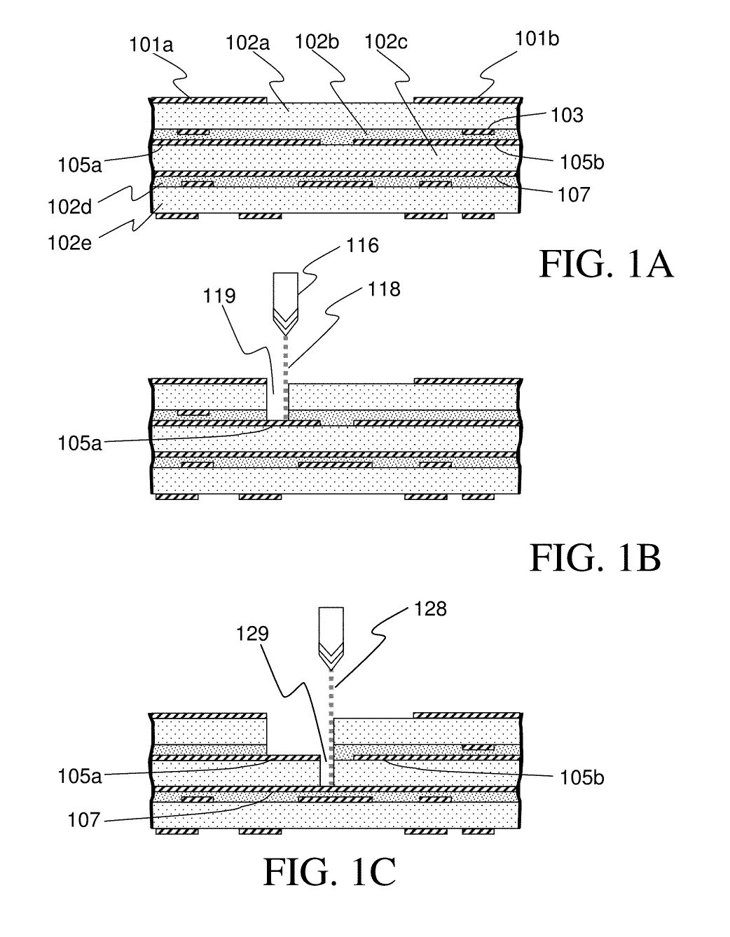

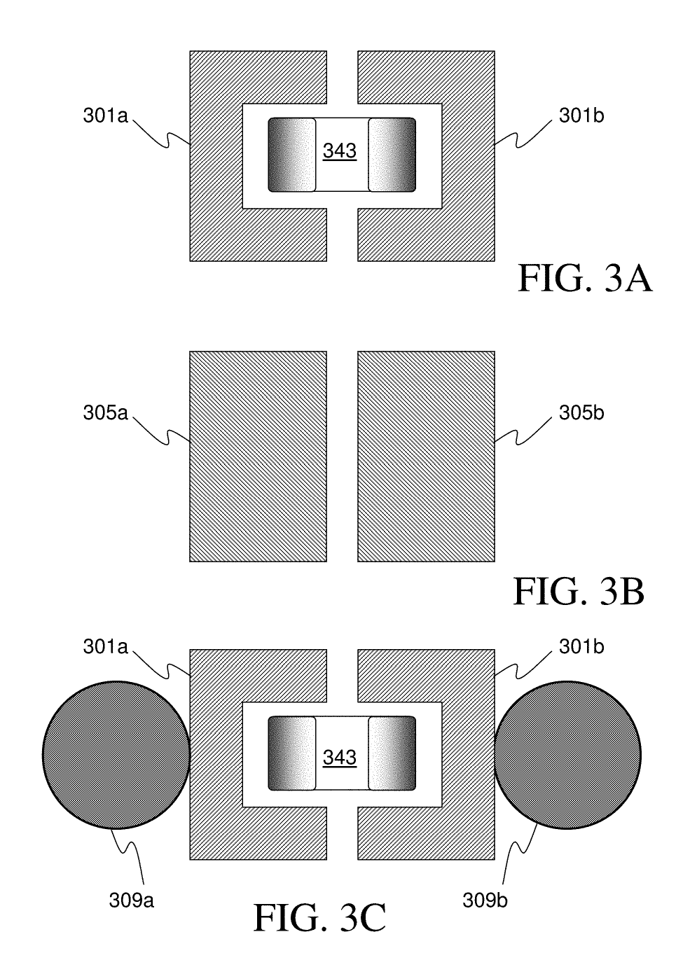

Referring to FIG. 1A there may be seen a cross-sectional view of a portion of a fine-pitch through-hole multilayer circuit board. The pads 101a and 101b are on the top layer of the printed circuit board and further detailed in FIG.s 3A and 3C. Insulating resin layers 102a-102e separate the conductive portions of the multilayer board. Conductive trace 103 represents a trace on the first signal layer, while conductive areas 105a and 105b, which are further detailed in FIG. 3B are located on a second signal layer. The conductive areas 105a and 105b carry two roles. First they will ultimately act as soldering points for a surface mount component, and second they will act as a stop layer for a laser drill to be described in conjunction with FIG. 1B.

Referring to FIG. 1B there may be seen the cross-sectional view of a portion of a fine-pitch through-hole multilayer circuit board of FIG. 1A with a laser 116 using its beam 118 to excavate a cavity 119 in the circuit board. Conductive area 105a, normally of copper, acts as a dimensional “stop” for the laser beam 118, setting the depth for the excavated recess. The beam 118 vaporizes the insulating resin layers above the conductive area 105a, leaving the area available as a component soldering pad, as will be described below.

Referring to FIG. 1C there may be seen the cross-sectional view of the portion of a fine-pitch through-hole multilayer circuit board of FIG. 1B with the laser having continued further excavation. The beam 128 may be seen excavating to a further depth 129 with a conductive portion 107 acting as the “stop” for the beam. Conductive portion 107 normally would be a portion of the power or ground planes within the multilayer circuit board. The further depth portion between conductive areas 105a and 105b will act as an insulative gap between these conductive areas when the areas are later used as component soldering pads.

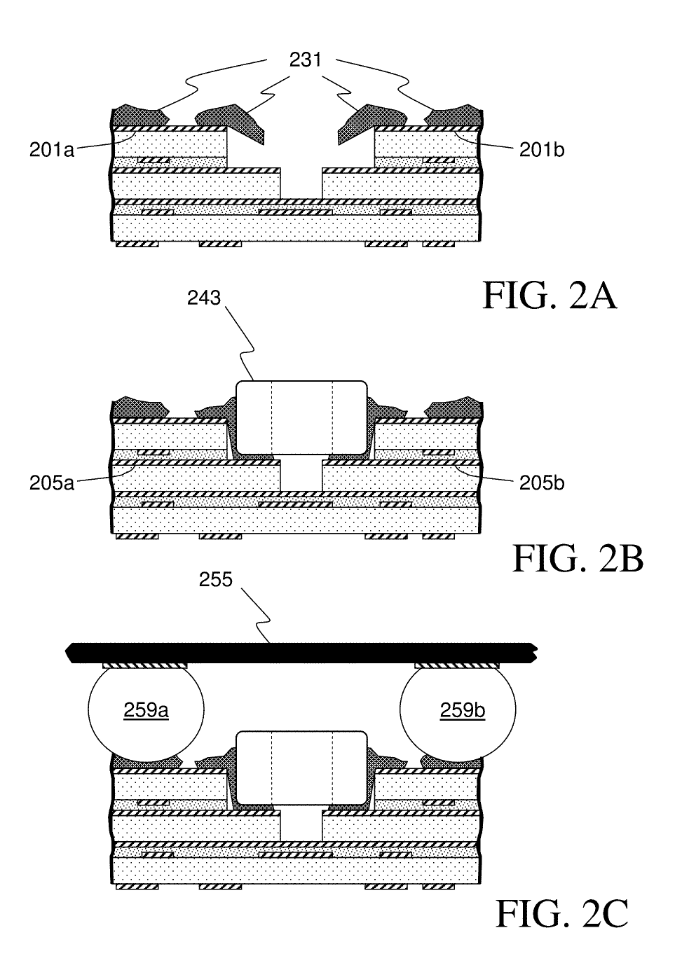

Referring to FIG. 2A, there may be seen the cross-sectional view of the portion of a fine-pitch through-hole multilayer circuit board of FIG. 1C with the laser having completed excavation. Solder paste quantities 231 have been placed on the printed circuit board on conductive pad areas 201a and 201b.

In FIG. 2B a surface mount component 243 has been inserted into the recess, distributing the solder paste onto the conductive area pads 205a and 205b. In general this component will be a decoupling capacitor. Other types of surface mount components can alternatively be placed into the recess, including two-port devices such as resistors and diodes.

Referring to FIG. 2C there may be seen a cross-sectional view Ball Grid Array placed onto the portion of a fine-pitch through-hole multilayer circuit board depicted in FIG. 2B. The bottom portion 255 of the BGA has solder balls 259a and 259b which are lodged into respective portions of solder paste. A subsequent reflow soldering operation will secure both the BGA and surface mount component to their respective contact pads on the printed circuit board.

Referring now to FIG.s 3A to 3C there may be seen top views of conductive land patterns, typically copper, which correspond to the previous Figures. In FIG. 3A may be seen the generally U-shaped conductive pads 301a and 301b on the top layer of the multilayer circuit board. These pads correspond to the conductive cross-sections 101a and 101b respectively of FIG. 1A and surround the recess in which the surface mount component 343 is placed.

In FIG. 3B may be seen the conductive pads which the bottom of component 343 is ultimately soldered. These conductive pads correspond to the conductive cross-sections 105a and 105b respectively of FIG. 1A and as previously described also act as the “stop” for the laser milling process to define the bottom of the recess in those areas.

Referring now to FIG. 3C there may be seen printed circuit board component pads 309a and 309b which comprise a portion of the grid of pads to which the BGA component is soldered. These component pads 309a and 309b are respectively conductively connected to the U-shaped conductive pads 301a and 301b. As well, printed circuit board via connections also conductively connect the interior layer conductive pads 305a and 305b to component pads 309a and 309b respectively, the vias offering a degree of additional reliability of conductive connection between the component pads and the surface mount component 343 upon completion of the reflow soldering operation.

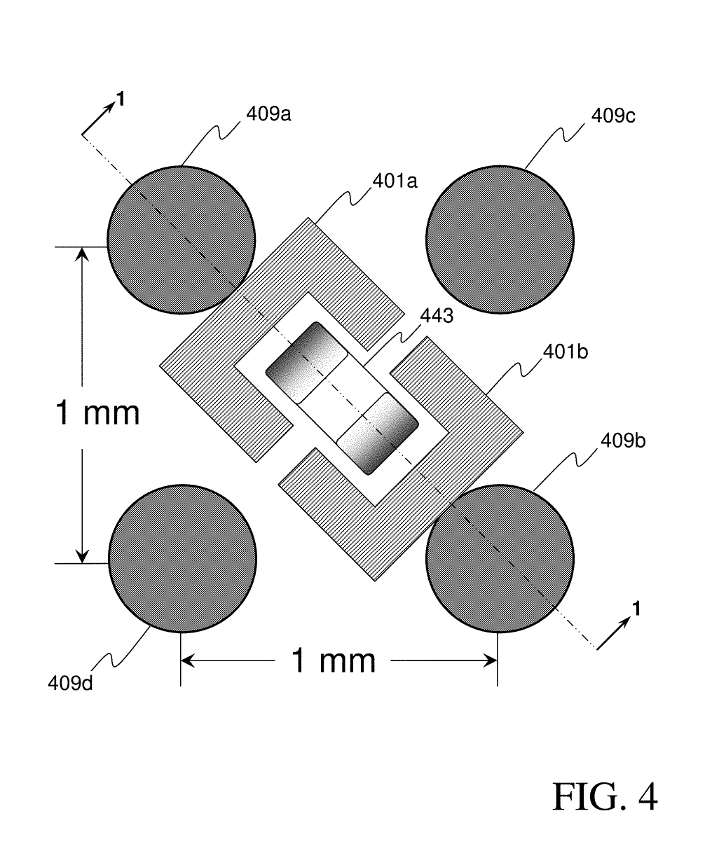

Referring now to FIG. 4, there may be seen a top view of an embodiment of the invention within a portion of a grid of printed circuit board component pads 409a to 409d to which a BGA would be soldered. In this embodiment the BGA grid is a regular grid having a 1 mm pitch, allowing sufficient space for U-shaped conductive pads 401a and 401b, a recess, and surface mount component 443 of nominal industry size “0201” in dimension. Smaller components, such as the nominal industry size “01005” could likewise be situated in a similar configuration with the appropriate dimensional adaptation of the U-shaped conductive pads and recess.

According to another embodiment of the invention, larger component sizes, such as nominal industry sizes “0402” and “0603” may also be placed within the BGA grid pattern by both appropriate dimensional adaptation of the U-shaped conductive pads and recess, and by depopulating certain BGA component pads (and corresponding balls on the BGA component). As well, by depopulating certain BGA component pads and corresponding balls on the BGA component, embodiments of the invention may be implemented on regular grids of other than a 1 mm pitch, for example those having a 0.8 mm pitch. Alternatively, embodiments of the invention may also be implemented on non-regular grids, providing flexibility in component placement appropriate to the Ball Grid Array to be positioned over the components.

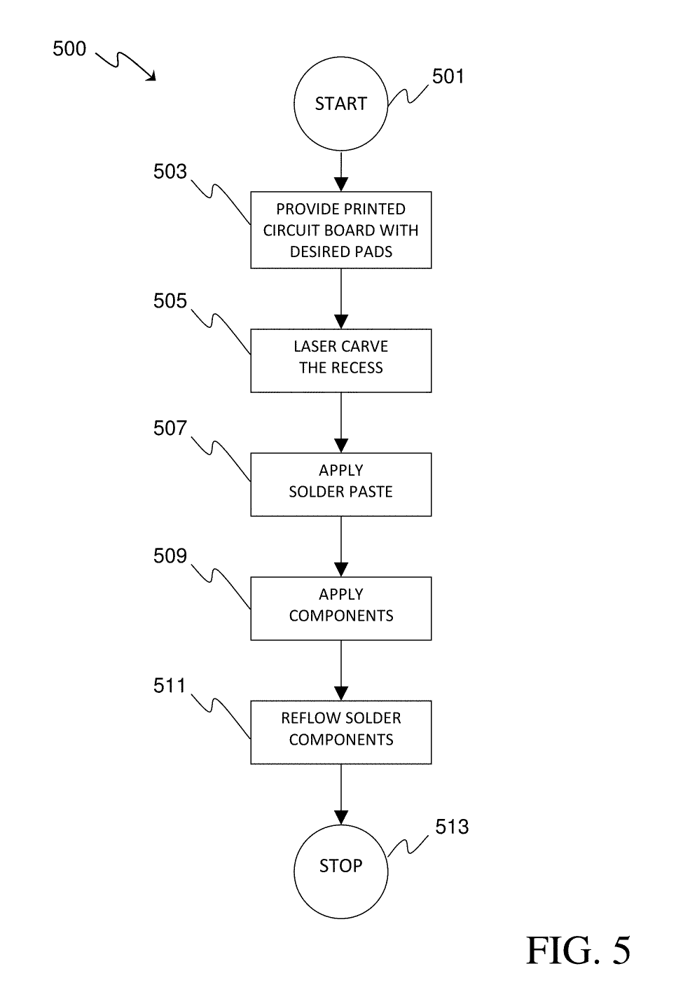

Referring to FIG. 5 there may be seen a flowchart 500 of the steps of a method according to an embodiment of the invention. The method commences at step 501. At step 503 a fine-pitch through-hole multilayer circuit board is provided having component pads and conductive connections thereof appropriate to the surface mount components to be placed. At step 505 a laser milling operation carves the appropriate recesses for the surface mount components which are to be located beneath respective Ball Grid Array components. As previously described, interior conductive pads have been placed to act as “stops” for the laser milling operation. At step 507 solder paste is applied to the circuit board, and at step 509 the surface mount components are placed such that their appropriate conductive pads and balls are contacting the solder paste. At step 511 a soldering reflow operation is performed, reflowing the solder paste and conductively attaching the surface mount components. The method then terminates at step 513.

In an exemplary embodiment, a computer aided design tool allows the selection of conductive component pads on both the top layer and internal layers to be substantially automated. The computer aided design tool may automatically identify appropriate spacing and shape of the conductive pads to place standard components on within the respective BGA grid for attaching to the board within defined recesses. A computer aided design tool may also provide instructions to control a machine to manufacture the modified circuit board. Instructions may be exported to the machine or the design tool may directly control the machine.

Thus what has been disclosed is a method of placing surface mount components beneath Ball Grid Arrays in respective recesses, thus providing an alternate method of placing small components within close proximity of the Ball Grid Arrays.

While the figures and descriptions may depict regular circular or rectangular shapes of different elements in exemplary embodiments, it should be understood that alternative shapes may be used such as imperfect polygons and rounded forms. These alternative shapes may be substantially similar to the depicted shapes in area and outline.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications can be effected while remaining within the spirit and scope of the invention. Accordingly, the foregoing disclosure, description, and figures are for illustrative purposes only and do not in any way limit the invention, which is defined only by the claims.

What is claimed is:

1. A through-hole printed circuit board (PCB) comprising:
a ball grid array (BGA) of BGA pads on one side of the PCB, arranged in a tight-pitch grid pattern;
a milled recess on the same side of said PCB in said PCB adjacent and between a first and a second of said BGA pads of said ball grid array of BGA pads;
said recess sized to contain a Surface Mount Component (SMC);
a first pair of separated conductive pads at the bottom of said milled recess, each pad respectively conductively coupled to said first and second BGA pads.

2. The PCB of claim 1, wherein
a second pair of separated conductive pads surround the opening of said milled recess, each pad respectively conductively coupled to said first and second BGA pads.

3. The PCB of claim 1, wherein
said tight-pitch grid pattern has a 1 mm pitch.

4. The PCB of claim 3, wherein
said SMC has a industry nominal 0201 size; and
said first and second BGA pads are diagonally situated relative to said grid pattern.

5. The PCB of claim 3, wherein
said SMC has a industry nominal 01005 size; and
said first and second BGA pads are diagonally situated relative to said grid pattern.

6. The PCB of claim 1, wherein
at least one BGA pad of said ball grid array of BGA pads has been removed; and
said milled recess is located in the array grid where said at least one BGA has been removed.

7. The PCB of claim 6, wherein
said SMC has a industry nominal 01005 size.

8. The PCB of claim 6, wherein
said SMC has a industry nominal 0201 size.

9. The PCB of claim 6, wherein
said SMC has a industry nominal 0402 size.

10. The PCB of claim 6, wherein
said SMC has a industry nominal 0603 size.

11. The PCB of claim 1, wherein
said milled recess was milled by a laser.

12. A method of manufacturing a multilayer PCB wherein the PCB has a ball grid array (BGA) of BGA pads on one side of the PCB arranged in a grid pattern; the method comprising the steps of:
milling a recess on the same side of said PCB in said PCB adjacent and between a first and a second of said BGA pads of said ball grid array of BGA pads, the bottom of said recess having arranging a first pair of separated conductive pads at the bottom of said milled recess, each pad respectively conductively coupled to said first and second BGA pads;
sizing said recess to contain a Surface Mount Component (SMC);
placing solder paste in said first pair of separated conductive pads;
placing solder paste on said ball grid array (BGA) of BGA pads;
placing an SMC within said recess;
placing a BGA component over said SMC;
reflow soldering said SMC component and said BGA component.

13. The method of claim 12, wherein
said milling is performed by a laser.

14. The method of claim 12, wherein
said multilayer PCB having a second pair of separated conductive pads surrounding the opening of said milled recess, each pad respectively conductively coupled to the same first and second BGA pads as the respective conductive pads at the same end of said recess; and
prior to the step of placing an SMC within said recess, placing solder paste on said second pair of separated conductive pads.

15. The method of claim 12, wherein
said SMC is a capacitor.

16. The method of claim 12, wherein
said first and second BGA pads are diagonally situated relative to said grid pattern.

17. The method of claim 12, wherein
at least one BGA pad of said ball grid array of BGA pads has been removed; and
the milling of said recess is located in the array grid where said at least one BGA has been removed.

18. A computer aided design tool implemented on a computing device for accommodating a multilayer printed circuit board (PCB) wherein the PCB has a ball grid array (BGA) of BGA pads on one side of the PCB arranged in a grid pattern comprising:
a design tool mode configured to select two adjacent BGA pads on the printed circuit board (PCB) for connection to a two-lead component;
a design tool mode configured to identify a placement of a recess between said two BGA pads for containing a Surface Mount Component (SMC);
a design tool mode configured to identify a placement of separated component pads on an inner layer of said PCB so as to define a bottom of said recess; and
a design tool mode configured to conductively connect said separated component pads to a respective BGA pad of said two BGA pads.

19. The computer aided design tool of claim 18 further comprising:
a design tool mode configured to identify a placement of a second pair of separated conductive pads surrounding the opening of said milled recess; and
a design tool mode configured to conductively connect said second pair respectively to the same first and second BGA pads as the respective conductive pads at the same end of said recess.

20. The computer aided design tool of claim 18 further comprising:
a design tool mode configured to identify remove at least one BGA pad from said ball grid array of BGA pads and situate said recess in the array grid where the BGA pad has been removed.
